(19) United States
(12) Patent Application Publication
(10) Pub. No.: US 2026/0135365 A1
(43) Pub. Date: May 14, 2026

(54) POWER TRANSMISSION ASSEMBLY AND IMMERSION COOLING TANK

(71) Applicant: Wiwynn Corporation, New Taipei City (TW)

(72) Inventors: HSIEN-CHIEH HSIEH, New Taipei City (TW); Fu Sheng Cheng, New Taipei City (TW)

(21) Appl. No.: 19/339,406

(22) Filed: Sep. 25, 2025

Related U.S. Application Data
(60) Provisional application No. 63/717,960, filed on Nov. 8, 2024.

(30) Foreign Application Priority Data
Jul. 23, 2025 (TW) 114207695

(51) Int. Cl. H02G 3/22; H05K 7/20

(52) U.S. Cl. CPC H02G 3/22; H05K 7/20763

(57) ABSTRACT

A power transmission assembly includes a positive transmission plate and a negative transmission plate. The positive transmission plate includes a first positive electrode, a second positive electrode and a third positive electrode. The second positive electrode is movably lapped over the first positive electrode. The third positive electrode is movably lapped over the second positive electrode. The negative transmission plate includes a first negative electrode, a second negative electrode, a third negative electrode and a fourth negative electrode. The first negative electrode is parallel to the first positive electrode. The second negative electrode is parallel to the second positive electrode and movably lapped over the first negative electrode. The third negative electrode is parallel to the second positive electrode and movably lapped over the second negative electrode. The fourth negative electrode is parallel to the third positive electrode and movably lapped over the third negative electrode.

### CROSS-REFERENCE TO RELATED APPLICATIONS

### This non-provisional application claims priority under 35 USC § 119a on Provisional Application No(s). 63/717,960 filed in USA on November 8th, 2024, and Patent Application No(s). 114207695filed in Taiwan R.O.C on July 23rd, 2025, the entire contents of which are hereby incorporated by reference.

### TECHNICAL FIELD

The disclosure relates to a power transmission assembly and an immersion cooling tank.

### BACKGROUND

With the advancement of technology, immersion liquid cooling techniques have been developed, in which servers are immersed in a coolant within a tank for heat dissipation. However, to improve power supply safety and to limit the size of the tank to save on the amount of the coolant, the server’s power supply is arranged outside the tank. Therefore, it is necessary to design a power transmission assembly capable of transmitting power from outside the tank to inside the tank.

### SUMMARY

Therefore, the disclosure is to provide a power transmission assembly and an immersion cooling tank, which are capable of transmitting power from outside the tank to inside the tank for supplying power to a server.

One embodiment of the disclosure provides a power transmission assembly. The power transmission assembly includes a positive transmission plate and a negative transmission plate. The positive transmission plate includes a first positive electrode, a second positive electrode and a third positive electrode. The second positive electrode is movably lapped over the first positive electrode. The third positive electrode is movably lapped over the second positive electrode. The negative transmission plate includes a first negative electrode, a second negative electrode, a third negative electrode and a fourth negative electrode. The first negative electrode is parallel to the first positive electrode. The second negative electrode is parallel to the second positive electrode and movably lapped over the first negative electrode. The third negative electrode is parallel to the second positive electrode and movably lapped over the second negative electrode. The fourth negative electrode is parallel to the third positive electrode and movably lapped over the third negative electrode.

Another embodiment of the disclosure provides an immersion cooling tank. The immersion cooling tank includes a tank, a frame, a passthrough and the aforementioned power transmission assembly. The tank includes a side wall formed with a window. The frame is fixed to an outer surface of the side wall and surrounds the window. The passthrough is disposed in the window. The power transmission assembly penetrates through the passthrough.

The present power transmission assembly and the immersion cooling tank of the disclosure at least have the following advantage: (1) The frame is fixed to an outer surface of the side wall and surrounds the window, the passthrough is disposed in the window, and the power transmission assembly penetrates the passthrough, thereby enabling power to be transmitted from outside the tank to inside the tank to supply the server. (2) The passthrough ensures the sealing of the location where the power transmission assembly penetrates the tank. (3) The design in which the first positive electrode, the second positive electrode, and the third positive electrode of the positive transmission plate are movably lapped over one and another, and the first negative electrode, the second negative electrode, the third negative electrode, and the fourth negative electrode of the negative transmission plate are movably lapped over one and another, manufacturing tolerances are adapted.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of an immersion cooling tank according to one embodiment of the disclosure;

FIG. 2 is an exploded view of an immersion cooling tank according to one embodiment of the disclosure;

FIG. 3 is a partial exploded view of a power transmission assembly according to one embodiment of the disclosure;

FIG. 4 is a partial exploded view of a power transmission assembly according to one embodiment of the disclosure;

FIG. 5 is a partial side view of an immersion cooling tank according to one embodiment of the disclosure; and

FIG. 6 is a partial exploded view of a power transmission assembly according to one embodiment of the disclosure.

### DETAILED DESCRIPTION

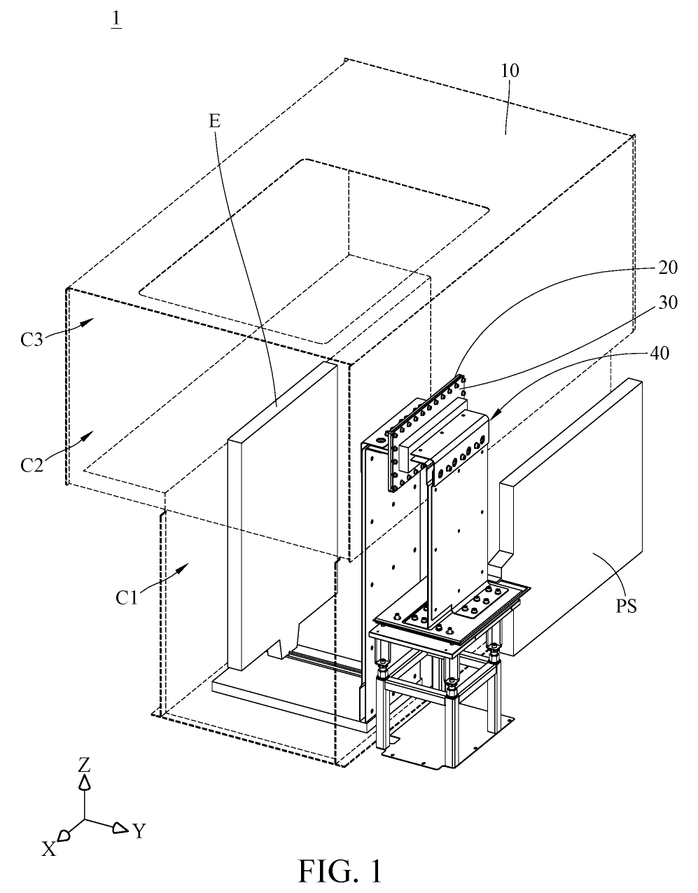

FIG. 1 is a perspective view of an immersion cooling tank 1 according to one embodiment of the disclosure. The immersion cooling tank 1 includes a tank 10, a frame 20, a passthrough 30, and a power transmission assembly 40. The power transmission assembly 40 is configured to transmit electrical power supplied by a power supply PS from outside the tank 10 to an electronic device E inside the tank 10. A non-conductive coolant (not shown) may be filled into the tank 10. After absorbing heat generated by the electronic device E, the coolant vaporizes into coolant vapor. Since the tank 10 is not completely filled with the coolant, air is also contained in the tank 10.

It should be understood that since gravitational force is proportional to mass, substances with greater mass or density tend to move toward the bottom of the tank 10 under gravity, while substances with smaller mass or density tend to move toward the top of the tank 10 due to the reaction force of the moving substances and buoyancy. In addition, since the density of the coolant is greater than that of the coolant vapor, and the molecular weight of the coolant vapor is greater than that of air and water vapor, a liquid area C1, a vapor area C2, and an air area C3 are naturally formed inside the tank 10, where the liquid area C1 is located at the lowest level, the air area C3 is located at the highest level, and the vapor area C2 is located between the liquid area C1 and the air area C3.

In some embodiments, at least one electronic device E is disposed in the liquid area C1. The power transmission assembly 40 is partially disposed in the liquid area C1, extends from the liquid area C1 to the vapor area C2, and further penetrates the tank 10 from the passthrough 30. The frame 20 and the passthrough 30 are disposed in the vapor area C2. Notably, since the liquid area C1 is located at the lowest level and is subjected to greater pressure (including atmospheric pressure, vapor pressure, and liquid pressure), configuring the power transmission assembly 40 to penetrate the tank 10 from the vapor area C2 can reduce the risk of coolant leakage. In other embodiments, configuring the power transmission assembly 40 to penetrate the tank 10 from the air area C3 can further reduce the risk of coolant vapor leakage.

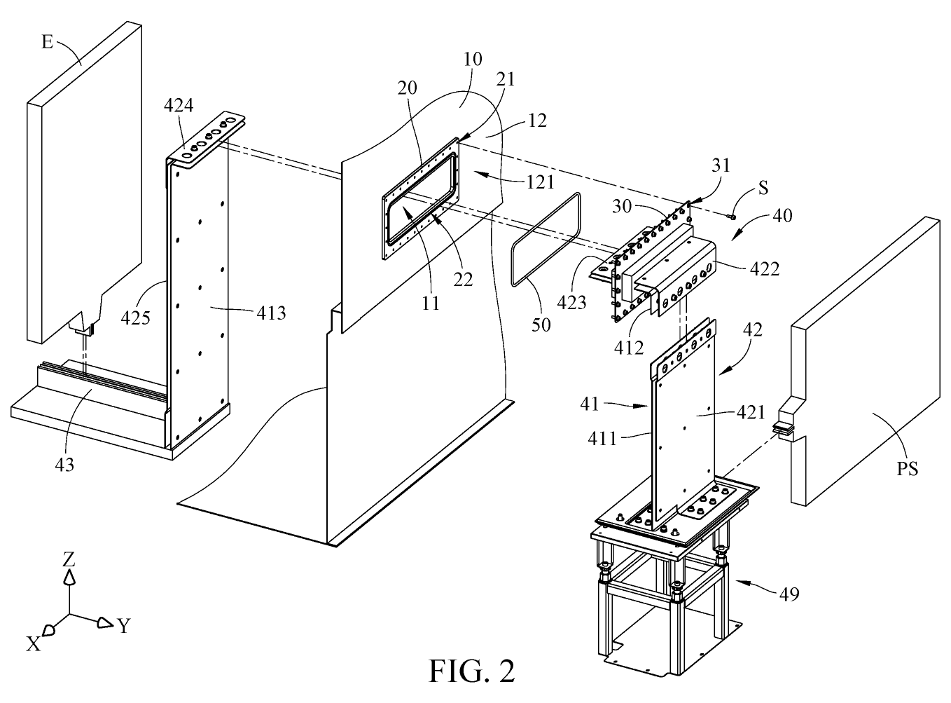

FIG. 2 is an exploded view of the immersion cooling tank 1 according to one embodiment of the disclosure. The tank 10 includes a side wall 12 formed with a window 11. The frame 20 is fixed to an outer surface 121 of the side wall 12 and surrounds the window 11. The passthrough 30 is disposed in the window 11 to seal the window 11. The power transmission assembly 40 penetrates the passthrough 30.

In some embodiments, the frame 20 is formed with a plurality of blind holes 21, and the passthrough 30 is formed with a plurality of through holes 31. A plurality of screws S penetrate the through holes 31 and are fastened in the blind holes 21, so as to secure the passthrough 30 to the frame 20.

In some embodiments, the immersion cooling tank 1 further includes a sealing ring 50, and the frame 20 is formed with a groove 22. The sealing ring 50 is disposed in the groove 22 and clamped between the passthrough 30 and the frame 20, thereby sealing where the passthrough 30 and the frame 20 are assembled.

The power transmission assembly 40 is disposed on a leveling table 49, and includes a positive transmission plate 41 and a negative transmission plate 42. The positive transmission plate 41 is configured to transmit a positive voltage or a high voltage, and the negative transmission plate 42 is configured to transmit a negative voltage or a low voltage, or to be grounded.

The positive transmission plate 41 includes a first positive electrode 411, a second positive electrode 412, and a third positive electrode 413. The second positive electrode 412 is movably lapped over the first positive electrode 411, and the third positive electrode 413 is movably lapped over the second positive electrode 412.

The negative transmission plate 42 includes a first negative electrode 421, a second negative electrode 422, a third negative electrode 423, and a fourth negative electrode 424. The first negative electrode 421 is parallel to the first positive electrode 411. The second negative electrode 422 is parallel to the second positive electrode 412 and is movably lapped over the first negative electrode 421. The third negative electrode 423 is parallel to the second positive electrode 412 and is movably lapped over the second negative electrode 422. The fourth negative electrode 424 is parallel to the third positive electrode 413 and is movably lapped over the third negative electrode 423. In this configuration, during installation or maintenance of the positive transmission plate 41 and the negative transmission plate 42, personnel can adaptively adjust the overlapped positions of the electrodes, thereby compensating tolerances among the electrodes.

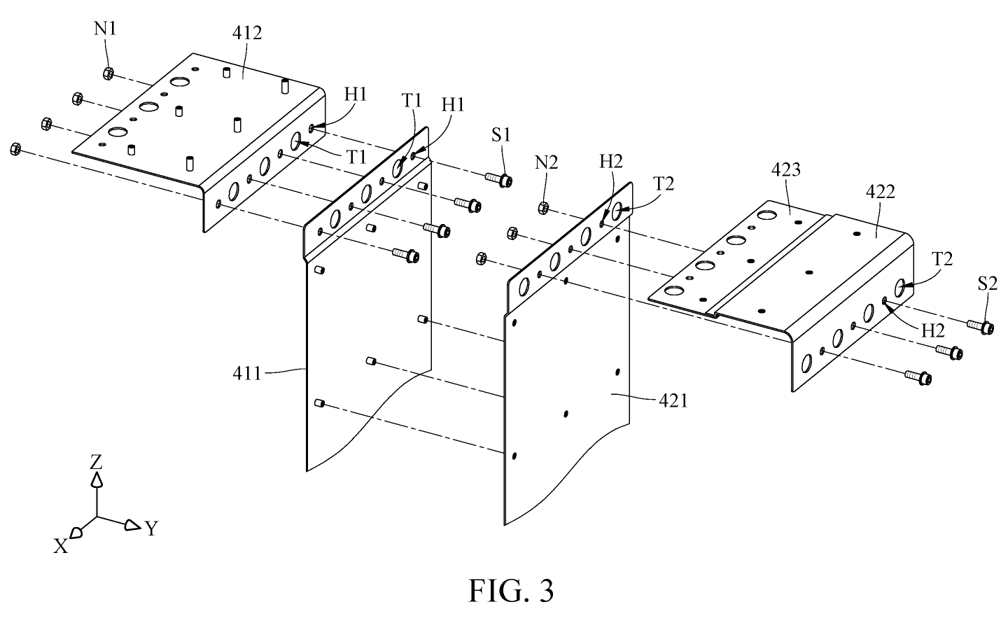

FIG. 3 is a partial exploded view of the power transmission assembly 40 according to one embodiment of the disclosure. In some embodiments, the positive transmission plate 41 further includes a plurality of first screws S1 and a plurality of first nuts N1. The first positive electrode 411 and the second positive electrode 412 are respectively formed with a plurality of first circular holes H1, where the size of the first circular holes H1 is greater than that of the first screws S1. The first screws S1 penetrate the first circular holes H1. The first nuts N1 are configured to be fastened to the first screws S1, thereby securing the first positive electrode 411 and the second positive electrode 412. Due to the configuration in which the size of the first circular holes H1 is greater than that of the first screws S1, slightly loosening the first nuts N1 allows the first positive electrode 411 and the second positive electrode 412 to move relative to each other, thereby adjusting their relative positions.

In some embodiments, the negative transmission plate 42 further includes a plurality of second screws S2 and a plurality of second nuts N2. The first negative electrode 421 and the second negative electrode 422 are respectively formed with a plurality of second circular holes H2, where the size of the second circular holes H2 is greater than that of the second screws S2. The second screws S2 penetrate the second circular holes H2. The second nuts N2 are configured to be fastened to the second screws S2, thereby securing the first negative electrode 421 and the second negative electrode 422. Due to the configuration in which the size of the second circular holes H2 is greater than that of the second screws S2, slightly loosening the second nuts N2 allows the first negative electrode 421 and the second negative electrode 422 to move relative to each other, thereby adjusting their relative positions.

In some embodiments, the first positive electrode 411 and the second positive electrode 412 are formed with a plurality of first through holes T1 arranged in the X direction, where each of the first through holes T1 is located between two of the first circular holes H1. The first negative electrode 421 and the second negative electrode 422 are formed with a plurality of second through holes T2 arranged in the X direction, where each of the second through holes T2 is located between two of the second circular holes H2. Onto the XZ plane, projections of the first circular holes H1 overlap with projections of the second through holes T2, and projections of the first through holes T1 overlap with projections of the second circular holes H2. In this manner, the first screws S1 installed in the first circular holes H1 and the second screws S2 installed in the second circular holes H2 do not interfere with each other.

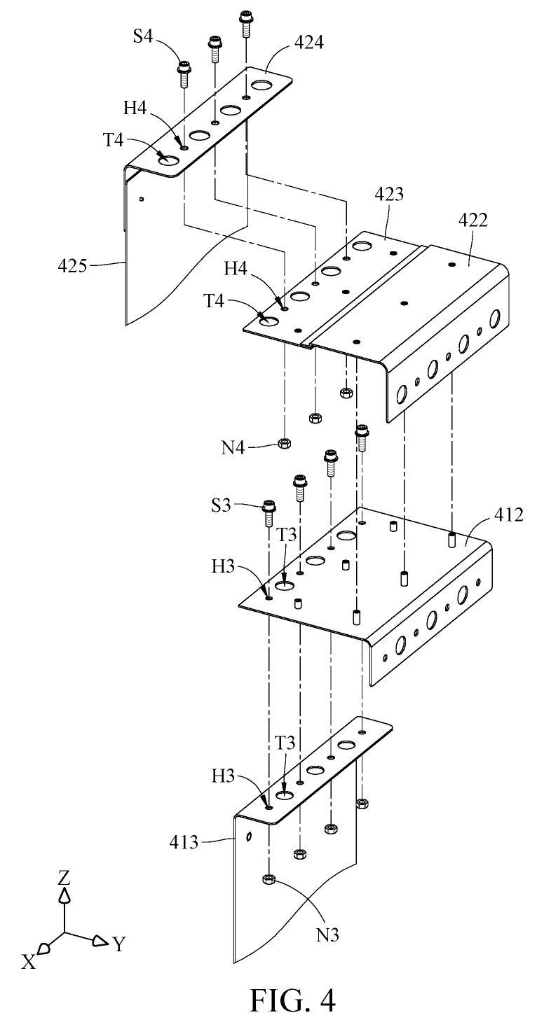

FIG. 4 is a partial exploded view of the power transmission assembly 40 according to one embodiment of the disclosure. In some embodiments, the positive transmission plate 41 may further include a plurality of third screws S3 and a plurality of third nuts N3. The second positive electrode 412 and the third positive electrode 413 are respectively formed with a plurality of third circular holes H3, where the size of the third circular holes H3 is greater than that of the third screws S3. The third screws S3 penetrate the third circular holes H3. The third nuts N3 are configured to be fastened to the third screws S3, thereby securing the second positive electrode 412 and the third positive electrode 413. Due to the configuration in which the size of the third circular holes H3 is greater than that of the third screws S3, slightly loosening the third nuts N3 allows the second positive electrode 412 and the third positive electrode 413 to move relative to each other, thereby adjusting their relative positions.

In some embodiments, the negative transmission plate 42 may further include a plurality of fourth screws S4 and a plurality of fourth nuts N4. The third negative electrode 423 and the fourth negative electrode 424 are respectively formed with a plurality of fourth circular holes H4, the size of the fourth circular holes H4 is greater than that of the fourth screws S4. The fourth screws S4 penetrate the fourth circular holes H4. The fourth nuts N4 are configured to be fastened to the fourth screws S4 to secure the third negative electrode 423 and the fourth negative electrode 424. Due to the configuration in which the size of the fourth circular holes H4 is larger than that of the fourth screws S4, slightly loosening the fourth nuts N4 allows the third negative electrode 423 and the fourth negative electrode 424 to move relative to each other, thereby adjusting their relative positions.

In some embodiments, the second positive electrode 412 and the third positive electrode 413 are formed with a plurality of third through holes T3 arranged in the X direction, where each of the third through holes T3 is located between two of the third circular holes H3. The third negative electrode 423 and the fourth negative electrode 424 are formed with a plurality of fourth through holes T4 arranged in the X direction, where each of the fourth through holes T4 is located between two of the fourth circular holes H4. Onto the XY plane, projections of the third circular holes H3 overlap with projections of the fourth through holes T4, and projections of the third through holes T3 overlap with projections of the fourth circular holes H4. In this manner, the third screws S3 installed in the third circular holes H3 and the fourth screws S4 installed in the fourth circular holes H4 do not interfere with each other.

In some embodiments, the negative transmission plate 42 may further include a fifth negative electrode 425. The fifth negative electrode 425 is parallel to the third positive electrode 413 and, for example, is connected to the fourth negative electrode 424 via screws or rivets.

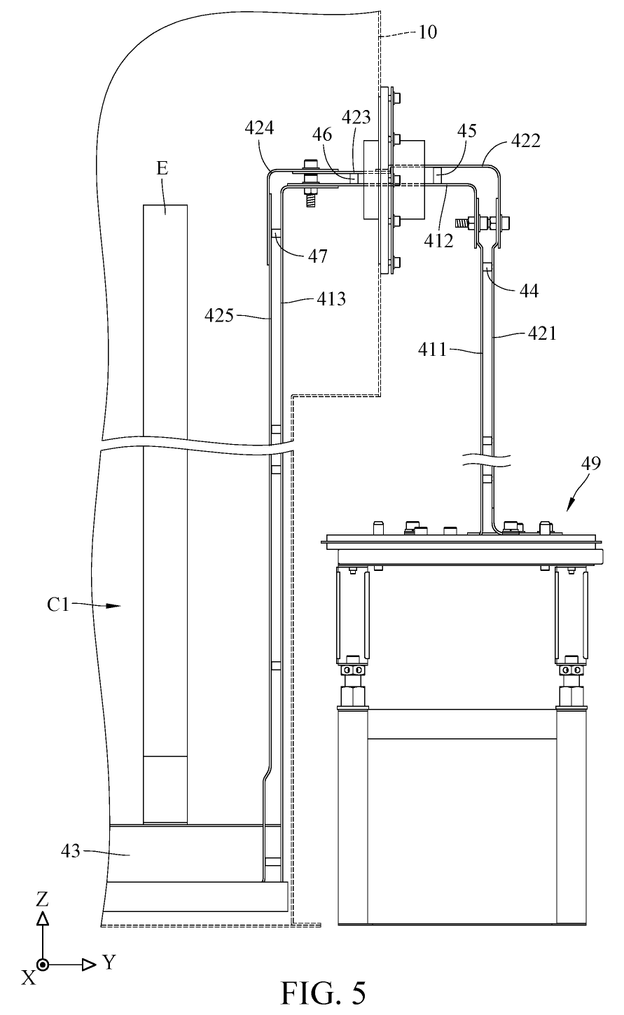

FIG. 5 is a partial side view of an immersion cooling tank 1 according to one embodiment of the disclosure. As can be seen from FIG. 5, the negative transmission plate 42 surrounds the positive transmission plate 41, such that the positive transmission plate 41 has a shorter transmission path to reduce transmission losses, and the peripheral negative transmission plate 42 can protect the positive transmission plate 41 to enhance safety.

In some embodiments, the power transmission assembly 40 may further include a busbar 43. The busbar 43 is disposed in the liquid area C1 of the tank 10 and is configured to be assembled with the electronic device E. The third positive electrode 413 and the fifth negative electrode 425 are electrically connected to a positive electrode and a negative electrode of the busbar 43, respectively.

In some embodiments, the first positive electrode 411, the first negative electrode 421, and the second negative electrode 422 respectively have a stepped shape and an L shape. The second positive electrode 412, the third positive electrode 413, and the fourth negative electrode 424 respectively have an L shape. In some embodiments, the step-shaped portion is bent at an angle of 45 degrees or 135 degrees, while the L-shaped portion has a 90-degree rounded corner.

In some embodiments, the power transmission assembly 40 may further include a first support insulator 44, a second support insulator 45, a third support insulator 46, and a fourth support insulator 47. The first support insulator 44 is disposed between the first positive electrode 411 and the first negative electrode 421. The second support insulator 45 is disposed between the second positive electrode 412 and the second negative electrode 422. The third support insulator 46 is disposed between the second positive electrode 412 and the third negative electrode 423. The fourth support insulator 47 is disposed between the third positive electrode 413 and the fourth negative electrode 424. In some embodiments, the fourth support insulator 47 is further disposed between the third positive electrode 413 and the fifth negative electrode 425. For example, the fourth support insulator 47 is disposed at where the fifth negative electrode 425 and the fourth negative electrode 424 are lapped over, so that the fourth support insulator 47 is simultaneously located between the fourth negative electrode 424 and the third positive electrode 413 as well as between the fifth negative electrode 425 and the third positive electrode 413.

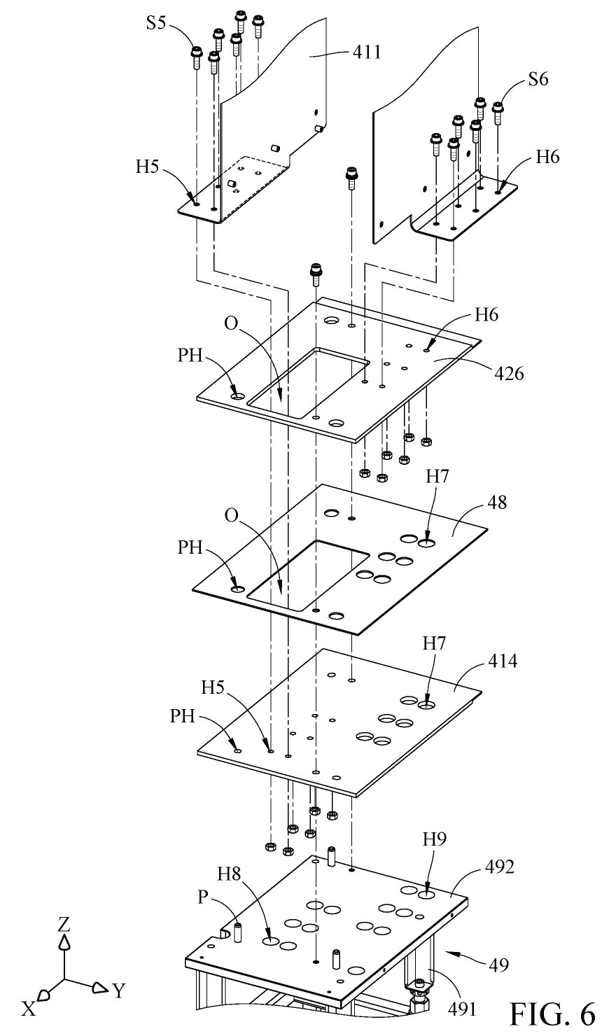

FIG. 6 is a partial exploded view of the power transmission assembly 40 according to one embodiment of the disclosure. In some embodiments, the positive transmission plate 41 may further include a positive substrate 414 and a plurality of fifth screws S5. The first positive electrode 411 and the positive substrate 414 are respectively formed with a plurality of fifth circular holes H5, and the fifth screws S5 are fastened into the fifth circular holes H5 to fix the first positive electrode 411 and the positive substrate 414 together. The positive substrate 414 is connected to the first positive electrode 411 and a positive power output of the power supply PS (as shown in FIG. 2).

In some embodiments, the negative transmission plate 42 may further include a negative substrate 426 and a plurality of sixth screws S6. The first negative electrode 421 and the negative substrate 426 are respectively formed with a plurality of sixth circular holes H6, and the sixth screws S6 are fastened into the sixth circular holes H6 to fix the first negative electrode 421 and the negative substrate 426 together. The negative substrate 426 is parallel to the positive substrate 414, and is connected to the first negative electrode 421 and a negative power output of the power supply PS (as shown in FIG. 2). In this way, the power supply PS can transmit power from outside the tank 10 to inside the tank 10 via the positive transmission plate 41, the negative transmission plate 42, and the busbar 43, thereby supplying power to the electronic device E (as shown in FIG. 2).

In some embodiments, the power transmission assembly 40 may further include an insulating plate 48. The insulating plate 48 is disposed above the positive substrate 414 and below the negative substrate 426, and is located between the positive substrate 414 and the negative substrate 426 so as to electrically insulate the positive substrate 414 from the negative substrate 426. In some embodiments, the negative substrate 426 and the insulating plate 48 are each formed with an opening O. The opening O exposes the fifth circular holes H5, and the fifth screws S5 are located in the opening O.

In some embodiments, the positive substrate 414 and the insulating plate 48 are respectively formed with a plurality of seventh circular holes H7. Diameters of the seventh circular holes H7 are greater than those of the sixth circular holes H6, and projections of the seventh circular holes H7 overlap with projections of the sixth circular holes H6. In this manner, the sixth screws S6 disposed in the sixth circular holes H6 do not interfere with the positive substrate 414 and the insulating plate 48.

In some embodiments, the power transmission assembly 40 may further include a leveling table 49. The leveling table 49 may include an adjustable bracket 491 and a platform 492, where the platform 492 is disposed on the adjustable bracket 491. The platform 492 is formed with a plurality of positioning posts P for inserting into a plurality of positioning holes PH of the positive substrate 414, the negative substrate 426, and the insulating plate 48.

In some embodiments, the platform 492 is formed with a plurality of eighth circular holes H8, and projections of the eighth circular holes H8 overlap with projections of the fifth circular holes H5. Thus, the fifth screws S5 disposed in the fifth circular holes H5 do not interfere with the platform 492. In some embodiments, the platform 492 is formed with a plurality of ninth circular holes H9, and projections of the ninth circular holes H9 overlap with projections of the sixth circular holes H6. Thus, the sixth screws S6 disposed in the sixth circular holes H6 do not interfere with the platform 492.

According to FIGS. 2 to 6, the assembly sequence of the power transmission assembly 40 is as follows:

Step (A): The third positive electrode 413 and the fifth negative electrode 425 are respectively inserted into the positive electrode and the negative electrode of the busbar 43.

Step (B): After the second positive electrode 412 and the third negative electrode 423 are installed into the passthrough 30, the screws S are fastened to secure the passthrough 30 to the frame 20.

Step (C): The second positive electrode 412 is lapped over the third positive electrode 413, and they are fastened with the third screw S3 and the third nut N3; After the third negative electrode 423 is lapped over the fourth negative electrode 424, and the fourth negative electrode 424 is lapped over the fifth negative electrode 425, the third negative electrode 423 and the fourth negative electrode 424 are fastened with the fourth screws S4 and the fourth nuts N4, and the fourth negative electrode 424 and the fifth negative electrode 425 are fastened with screws.

Step (D): The insulating plate 48 is disposed between the positive substrate 414 and the negative substrate 426; the first positive electrode 411 is lapped over the positive substrate 414, and they are fastened with the fifth screws S5; the first negative electrode 421 is lapped over the negative substrate 426, and they are fastened with the sixth screws S6.

Step (E): The first positive electrode 411 is lapped over the second positive electrode 412, and they are fastened with the first screws S1 and the first nuts N1; After the first negative electrode 421 is lapped over the second negative electrode 422, and the second negative electrode 422 is lapped over the third negative electrode 423, the first negative electrode 421 and the second negative electrode 422 are fastened with the second screws S2 and the second nut N2.

Step (F): The negative substrate 426, the insulating plate 48, and the positive substrate 414 are secured on the platform 492 of the leveling table 49; the height of the leveling table 49 is adjusted via the adjustable bracket 491 to accommodate the height difference between the power transmission assembly 40 and the ground.

In summary, the present power transmission assembly and immersion cooling tank at least have the following advantage: (1) The frame is fixed to an outer surface of the side wall and surrounds the window, the passthrough is disposed in the window, and the power transmission assembly penetrates the passthrough, thereby enabling power to be transmitted from outside the tank to inside the tank to supply to the server. (2) The passthrough ensures the sealing of the location where the power transmission assembly penetrates the tank. (3) The design in which the first positive electrode, the second positive electrode, and the third positive electrode of the positive transmission plate are movably lapped over one and another, and the first negative electrode, the second negative electrode, the third negative electrode, and the fourth negative electrode of the negative transmission plate are movably lapped over one and another, manufacturing tolerances are adapted.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A power transmission assembly, comprising:
a positive transmission plate, comprising:
a first positive electrode;
a second positive electrode movably lapped over the first positive electrode; and
a third positive electrode movably lapped over the second positive electrode; and
a negative transmission plate, comprising:
a first negative electrode parallel to the first positive electrode;
a second negative electrode parallel to the second positive electrode and movably lapped over the first negative electrode;
a third negative electrode parallel to the second positive electrode and movably lapped over the second negative electrode; and
a fourth negative electrode parallel to the third positive electrode and movably lapped over the third negative electrode.

2. The power transmission assembly according to claim 1, wherein the positive transmission plate further comprises:
a plurality of first screws, wherein the first positive electrode and the second positive electrode are respectively formed with a plurality of first circular holes, and the plurality of first screws penetrate the plurality of first circular holes; and
a plurality of first nuts configured to be fastened to the plurality of first screws so as to secure the first positive electrode and the second positive electrode.

3. The power transmission assembly according to claim 2, wherein the negative transmission plate further comprises:
a plurality of second screws, wherein the first negative electrode and the second negative electrode are respectively formed with a plurality of second circular holes, and the plurality of second screws penetrate the plurality of second circular holes; and
a plurality of second nuts configured to be fastened to the plurality of second screws so as to secure the first negative electrode and the second negative electrode.

4. The power transmission assembly according to claim 3, wherein:
the first positive electrode and the second positive electrode are formed with a plurality of first through holes, each of the plurality of first through holes is located between two of the plurality of first circular holes;
the first negative electrode and the second negative electrode are formed with a plurality of second through holes, each of the plurality of second through holes is located between two of the plurality of second circular holes; and
projections of the plurality of first circular holes overlap with projections of the plurality of second through holes, and projections of the plurality of first through holes overlap with projections of the plurality of second circular holes.

5. The power transmission assembly according to claim 1, wherein the positive transmission plate further comprises:
a plurality of third screws, wherein the second positive electrode and the third positive electrode are respectively formed with a plurality of third circular holes, and the plurality of third screws penetrate the plurality of third circular holes; and
a plurality of third nuts configured to be fastened to the plurality of third screws so as to secure the second positive electrode and the third positive electrode.

6. The power transmission assembly according to claim 5, wherein the negative transmission plate further comprises:
a plurality of fourth screws, wherein the third negative electrode and the fourth negative electrode are respectively formed with a plurality of fourth circular holes, and the plurality of fourth screws penetrate the plurality of fourth circular holes; and
a plurality of fourth nuts configured to be fastened to the plurality of fourth screws so as to secure the third negative electrode and the fourth negative electrode.

7. The power transmission assembly according to claim 1, further comprising:
a first support insulator disposed between the first positive electrode and the first negative electrode;
a second support insulator disposed between the second positive electrode and the second negative electrode;
a third support insulator disposed between the second positive electrode and the third negative electrode; and
a fourth support insulator disposed between the third positive electrode and the fourth negative electrode.

8. The power transmission assembly according to claim 7, wherein the negative transmission plate surrounds the positive transmission plate, and the negative transmission plate further comprises:
a fifth negative electrode parallel to the third positive electrode and connected to the fourth negative electrode, wherein the fourth support insulator is disposed between the third positive electrode and the fifth negative electrode.

9. The power transmission assembly according to claim 1, wherein the positive transmission plate further comprises:
a positive substrate connected to the first positive electrode and a positive power output of a power supply; and
a plurality of fifth screws, wherein the first positive electrode and the positive substrate are respectively formed with a plurality of fifth circular holes, and the plurality of fifth screws are fastened into the plurality of fifth circular holes so as to secure the first positive electrode and the positive substrate.

10. The power transmission assembly according to claim 9, wherein the negative transmission plate further comprises:
a negative substrate parallel to the positive substrate and connected to the first negative electrode and a negative power output of the power supply; and
a plurality of sixth screws, wherein the first negative electrode and the negative substrate are respectively formed with a plurality of sixth circular holes, and the plurality of sixth screws are fastened into the plurality of sixth circular holes so as to secure the first negative electrode and the negative substrate.

11. The power transmission assembly according to claim 10, wherein the negative substrate is formed with an opening, the opening exposes the plurality of fifth circular holes, and the plurality of fifth screws are located in the opening.

12. The power transmission assembly according to claim 10, wherein the negative substrate is disposed on the positive substrate, the positive substrate is formed with a plurality of seventh circular holes, diameters of the plurality of seventh circular holes are greater than diameters of the plurality of sixth circular holes, and projections of the plurality of seventh circular holes overlap with projections of the plurality of sixth circular holes.

13. The power transmission assembly according to claim 12, further comprising a leveling table, comprising:
an adjustable bracket; and
a platform disposed on the adjustable bracket, wherein the platform is formed with a plurality of positioning posts configured to be inserted into a plurality of positioning holes of the positive substrate and the negative substrate.

14. The power transmission assembly according to claim 13, wherein:
the platform is formed with a plurality of eighth circular holes, wherein the plurality of eighth circular holes overlap with projections of the plurality of fifth circular holes; and
the platform is formed with a plurality of ninth circular holes, wherein projections of the plurality of ninth circular holes overlap with projections of the plurality of sixth circular holes.

15. The power transmission assembly according to claim 1, wherein the first positive electrode, the first negative electrode, and the second negative electrode respectively have a stepped shape and an L shape.

16. The power transmission assembly according to claim 1, wherein the second positive electrode, the third positive electrode, and the fourth negative electrode respectively have an L shape.

17. An immersion cooling tank, comprising:
a tank comprising a side wall formed with a window;
a frame fixed to an outer surface of the side wall and surrounding the window;
a passthrough disposed in the window; and
the power transmission assembly according to claim 1 penetrating through the passthrough.

18. The immersion cooling tank according to claim 17, wherein the frame is formed with a plurality of blind holes, the passthrough is formed with a plurality of through holes, and a plurality of screws penetrate the plurality of through holes and are fastened into the plurality of blind holes.

19. The immersion cooling tank according to claim 17, further comprising a sealing ring, wherein the frame is formed with a groove, and the sealing ring is disposed in the groove.

20. The immersion cooling tank according to claim 17, wherein the tank is formed with a liquid area and a vapor area, a portion of the power transmission assembly is disposed in the liquid area, and the frame and the passthrough are disposed in the vapor area.
